(19) United States
(12) Patent Application Publication
(10) Pub. No.: US 2007/0020909 A1
(43) Pub. Date: Jan. 25, 2007

(54) Forming of conductive bumps for an integrated circuit

(75) Inventor: Franck Dosseul, Fondettes (FR)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics S.A., Montrouge (FR)

(21) Appl. No.: 11/491,838

(22) Filed: Jul. 24, 2006

(30) Foreign Application Priority Data
Jul. 25, 2005 (FR) 05/52303

(51) Int. Cl. H01L 21/44

(52) U.S. Cl. 438/612

(57) ABSTRACT

A method for forming conductive bumps on conductive pads formed on an electronic circuit wafer, comprising the steps of: including forming a resist mask with holes above the pads; depositing balls in the holes; performing a thermal processing to melt the balls; and eliminating the mask.

### BACKGROUND OF THE INVENTION

1. Field of the Invention

The present invention generally relates to the manufacturing of electronic circuits and, more specifically, to the forming of conductive bumps for making contacts with the circuits when flip-chip assembling on another circuit or on a support of printed circuit type.

The present invention more specifically applies to the forming of conductive bumps by full wafers of circuits before sawing for individualization of these circuits.

2. Discussion of the Related Art

FIGS. 1A and 1B illustrate, in simplified cross-section views, a conventional example of a method for forming conductive bumps on a wafer 1 in which electronic circuits (not shown) have been formed. These may be passive and/or active components, discrete or in a circuit. Once the circuit manufacturing is over, wafer 1 is assembled in a tool 2 formed of two tight peripheral rings 21 and 22 to maintain, on wafer 1, a grid 3 comprising openings 31 at the locations intended to receive conductive bumps. Conductive balls 4 (most often made of a tin-based alloy) are positioned in holes 31 of grid 3. The assembly is then passed in a furnace so that the melting of balls 4 in housings 31 results in the forming of bumps 45 which are shown in FIG. 1B after removal of the grid.

A disadvantage of this technique is due to the thermal mass of the mechanical elements, in particular rings 21 and 22 of assembly of wafer 1 and of grid 3, generally made of molybdenum, which makes the obtaining of a homogeneous temperature difficult. This may result in misalignments of the bumps with respect to the receive areas (not shown) on wafer 1 due to different expansions of wafer 1 and of grid 3.

Another disadvantage is that the machining of a molybdenum mask 3 causes constraints in terms of step and diameter. In practice, this technique is limited to the forming of bumps with a diameter of several hundreds of micrometers (typically, from 100 to 300 μm) with a step greater than 400μm.

With the use of positioning tools, so-called embodiments with or without flux may be implemented. Generally, a flux is used to enable temporary bonding of the material (alloy) forming the deposited balls on the receive areas.

Other techniques for forming conductive bumps providing the deposition, in a mask, of a soldering flux then submitted to a remelting to obtain the bumps and their definitive shapes, are also known.

A first example of a method of this type is described in European patent application No. 0655779 and provides forming a resin mask to define receive areas on a titanium and copper alloy conductive layer, depositing a paste in the mask holes, eliminating the mask, etching the titanium and copper receive area according to the pattern of areas intended to remain under the bumps, and causing a remelting so that the conductive bumps take their definitive shapes.

A disadvantage of this method is that the usable alloys are limited. Another disadvantage is the implementation cost due to the slowness of the method, which is directly linked to the thickness of the soldering flux deposition in the holes.

European patent No. 0655779 also discusses as the state of the art a method using a mask and soldering flux, and providing deposition of a soldering flux in a metal or resin mask.

A disadvantage of the two above techniques is, it being flux techniques, that they require a significant diameter. Indeed, approximately half the initial volume must be provided, this volume disappearing on remelting but however having to be provided for the forming of the mask holes.

Another disadvantage, in particular in the case of the use of a metal mask, is that this limits the range of usable materials due to the melting temperature that needs to remain low to avoid damaging the mask.

### SUMMARY OF THE INVENTION

The present invention aims at a novel technique for forming conductive bumps on an electronic circuit wafer which overcomes all or part of the disadvantages of known solutions.

The present invention more specifically aims at avoiding use of a tool with a significant thermal mass such as described in relation with FIGS. 1A and 1B.

The present invention also aims at providing a flux-less technique especially enabling decreasing the step and the diameters of the formed bumps.

The present invention also aims at providing a solution which allows various alloys to form the bumps.

The present invention also aims at a relatively fast method as compared with known techniques.

To achieve all or part of these objects, as well as others, the present invention provides a method for forming conductive bumps on conductive pads formed on an electronic circuit wafer, comprising the steps of:

forming a resist mask with holes above the pads;

depositing balls in the holes;

performing a thermal processing to melt the balls; and

eliminating the mask.

According to an embodiment of the present invention, the balls are submitted to a plasma pre-processing to improve their wettability.

According to an embodiment of the present invention, the receive areas are coated with gold.

According to an embodiment of the present invention, the balls have no welding flux.

According to an embodiment of the present invention, the balls are formed of a core of a first material coated with a second material having a melting temperature lower than the first one.

The present invention also aims at an electronic circuit comprising a network of bumps obtained by implementation of the above method.

The foregoing and other objects, features, and advantages of the present invention will be discussed in detail in the following non-limiting description of specific embodiments in connection with the accompanying drawings.

### BRIEF DESCRIPTION OF THE DRAWINGS

FIGS. 1A and 1B, previously described, illustrate a conventional technique for forming conductive bumps by deposition of preformed balls in a mask;

FIGS. 2A, 2B, 2C, 2D, and 2E are schematic cross-sectional views an embodiment of a method for forming conductive bumps according to the present invention; and

FIGS. 3A and 3B illustrate a variation of balls usable in the context of the present invention.

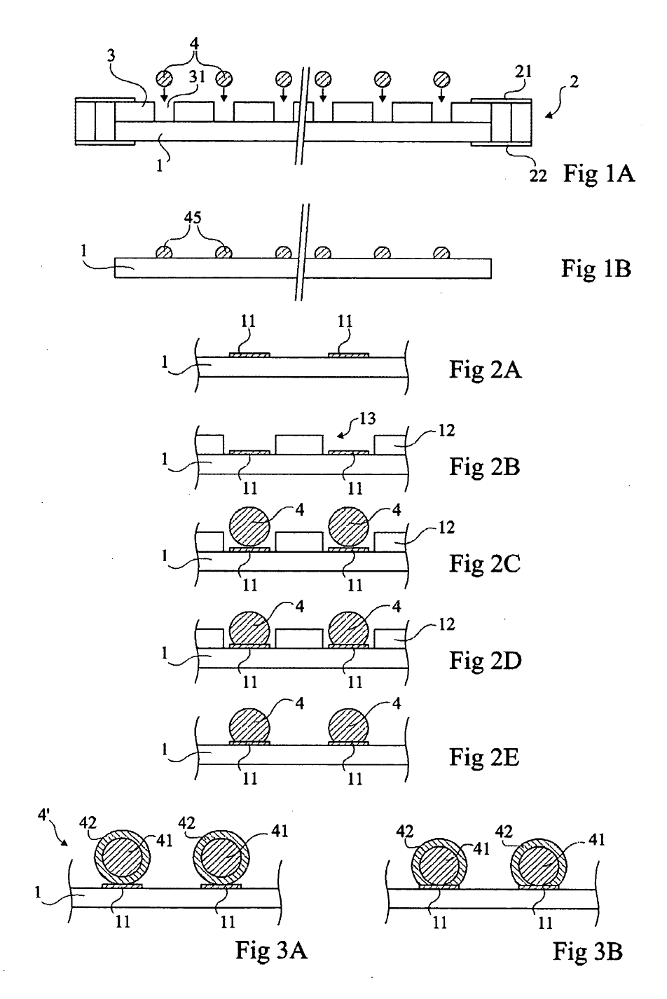

### DETAILED DESCRIPTION

The same elements have been designated with the same reference numerals in the different drawings and, further, as usual in the representation of integrated circuits, the various drawings are not to scale. For clarity, only those steps and elements which are useful to the understanding of the present invention have been shown in the drawings and will be described hereafter. In particular, the manufacturing steps of the circuits supported by the semiconductor wafer on which the conductive bumps have been formed have not been described in detail, the present invention being compatible with any conventional forming of electronic circuits. Similarly, the actual manufacturing steps using current techniques in the manufacturing of integrated circuits have not been described in detail.

FIGS. 2A to 2E are simplified cross-sectional views of a wafer 1 in which electronic circuits have been formed (passive components, discrete circuits, integrated circuits, etc.) at different steps of a preferred embodiment of the present invention.

A first step (FIG. 2A) comprises the forming, on contact recovery areas not shown, of conductive pads 11 for receiving conductive bumps. The forming of such pads is generally known as a UBM (Under Bump Metallization). The used material may be titanium, nickel, gold, titanium, copper alloys, and more generally any material used for this type of reception layer. Pads 11 are conventionally obtained by photoetching. Preferably, pads 11 are coated with gold or the like to avoid their oxidation.

In a second step (FIG. 2B), a mask 12 of resist or the like is formed by leaving openings 13 vertically above 11. Different techniques for forming mask 12 may be used. For example, a dry film deposition or a (wet) resin spin coating may be used. The etching then uses conventional resist photoetch steps.

In a third step (FIG. 2C), conductive balls 4 are deposited in holes 13 formed in mask 12. This deposition may use a conventional technique of deposition of balls 4 in a mask. For example, balls are deposited in a large number on the wafer and the assembly is shaken until a ball is present in each hole. The ball excess is eliminated by means, for example, of a scraper. In this case, the thickness of resin mask 12 is preferably smaller than or equal to the diameter of balls 4. It is indeed known to deposit and etch resin layers having thicknesses ranging from a few μm to a few hundreds of μm. For balls having a 80 μm diameter, a 50 μm thickness of resin mask 12 may be selected.

According to a preferred, though optional, embodiment of the present invention, balls 4 are pre-processed by plasma (for example, of type SF₆) to improve their temporary hold on conductive pads 11 without using a flux. In particular, such a processing enables passivating tin-based balls to improve their wettability when there are arranged in mask 12.

In a fourth step (FIG. 2D), the assembly is submitted to a thermal processing of remelting of balls 4, which then take their definitive shapes on pads 11. Such a remelting step generates no degassing in the preferred embodiment with no flux of the present invention. Further, this processing generates no specific thermal constraint since it requires neither a specific manipulation, nor any mechanical element added to wafer 1.

Finally, in a fifth and last step (FIG. 2E), resin mask 12 is eliminated, for 30 example, by any usual means for eliminating a resin mask from a wafer.

An advantage of the present invention is that it enables use of preformed conductive balls without requiring use of complex tools for positioning the balls.

Another advantage of the present invention, linked to the absence of a degassing, is that the present invention applies well to MEMS-type structures (with micro-electro-mechanical elements) and/or to structures comprising membranes.

Another advantage of the present invention is that no cleaning step is required at the end of the manufacturing since the use of a flux to deposit the soldering flux in the holes is avoided.

Another advantage of the present invention is that it enables obtaining bumps of small dimension (under 100 μm) with a step of less than 200 μm, without forbidding greater steps and diameters.

FIGS. 3A and 3B illustrate, in very simplified cross-section views, an alternative embodiment of the present invention in which balls 4′are bi-component balls. More specifically, a ball having a core 41 made of a hard material with a melting temperature greater than that used for the bump forming method is used. Core 41 is coated with a coating 42 of a fusible material in the fourth step of the above-described method. For example, the core of the conductive balls may be a metal such as nickel, copper, etc., and the coating may be tin or a tin-based alloy (for example, a tin and silver alloy). The use of balls of tin-coated polymer or of a tin-based alloy may even be envisaged.

An advantage of this embodiment is to obtain improved thermal and conductive characteristics of the balls with respect to those of the material forming the coating, which should be fusible to enable assembly thereof on receive areas 11.

FIG. 3A shows balls 4′on receive areas 11 (for simplification, in FIG. 3A, mask 12 has not been shown but it is however present) before melting of the coating. FIG. 3B illustrates the finished bumps, the melting of coating 42 having brought cores 41 in contact with pads 11.

Of course, the present invention is likely to have various, alterations, improvements, and modifications which will readily occur to those skilled in the art. In particular, the selection of the dimensions and of the step of the conductive balls is within the abilities of those skilled in the art based on the functional indications given hereabove and on the aimed application.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for forming conductive bumps on conductive pads formed on an electronic circuit wafer, comprising:
forming a resist mask with holes above the pads;
depositing balls in the holes;
performing a thermal processing to melt the balls; and
eliminating the mask.

2. The method of claim 1, wherein the balls are submitted to a plasma pre-processing to improve their wettability.

3. The method of claim 1, wherein the receive areas are coated with gold.

4. The method of claim 1, wherein the balls have no welding flux.

5. The method of claim 1, wherein the balls are formed of a core of a first material coated with a second material having a melting temperature lower than the first one.

6. An electronic circuit comprising a network of conductive bumps for transferring contacts to a reception surface, wherein the bumps are obtained by the method of claim 1.
